(19) United States
(12) Patent Application Publication
(10) Pub. No.: US 2006/0270185 A1
(43) Pub. Date: Nov. 30, 2006

(54) Method of forming isolation film of semiconductor device

(75) Inventor: In No Lee, Icheon-Si (KR)

Correspondence Address: MARSHALL, GERSTEIN & BORUN LLP, 233 S. WACKER DRIVE, SUITE 6300, SEARS TOWER, CHICAGO, IL, 60606, US

(73) Assignee: HYNIX SEMICONDUCTOR INC., Kyoungki-do (KR)

(21) Appl. No.: 11/442,197

(22) Filed: May 26, 2006

(30) Foreign Application Priority Data
May 30, 2005 (KR) 2005-45682

(51) Int. Cl. H01L 21/76

(52) U.S. Cl. 438/424

(57) ABSTRACT

A method of forming an isolation film of a semiconductor device wherein trenches are formed by etching a semiconductor substrate using HBr and O₂. Trench profiles with a slope can be formed, ISO gap fill can be facilitated, and voids are not generated. Accordingly, the invention is advantageous in that it can secure the reliability of devices and can improve the yield through ISO module process set-up.

### BACKGROUND

1. Field of the Invention

The invention relates generally to a method of forming an isolation film of a semiconductor device and, more particularly, to a method of forming an isolation film with a slope profile, of a semiconductor device.

2. Discussion of Related Art

In general, in the manufacturing process of the semiconductor devices, an isolation film is formed to separate elements that define an active region and a field region. As the degree of integration of the semiconductor devices increases, the isolation film is typically formed by a shallow trench isolation (STI) process of forming trenches at given regions of a semiconductor substrate and burying an insulating film into the trenches. The method of forming the isolation film using the STI process is summarized below.

A pad oxide film, a pad nitride film, and a hard mask are sequentially formed on a semiconductor substrate. A photoresist pattern is formed on the hard mask. The hard mask, the pad nitride film, and the pad oxide film are etched using the photoresist pattern as an etch mask, and the photoresist pattern is then stripped.

Thereafter, the semiconductor substrate is etched using Cl₂, HBr, and O₂, thus forming trenches. After a sidewall oxide film is formed on the trench sidewall, an insulating material is deposited on the entire surface so that the trenches are filled chemical mechanical polishing (CMP) is performed on the insulating material so that the pad nitride film is exposed, and the pad nitride film is then stripped to form an isolation film.

If the isolation film is formed as described above, however, Cl₂ is likely to be evaporated because a temperature at which Cl₂ can be vaporized is low (i.e., 58° C.) when reacting with the semiconductor substrate. Accordingly, a vertical profile having the slope of 88 degrees or more is formed and bowing occurs at the bottom portions of the profile. In this case, if an insulating material is deposited within the trenches, gap-fill is not complete and a void is formed.

Such voids cause bridges when depositing a polysilicon layer in order to form a gate in a subsequent process. Accordingly, there is a problem in that the void may hinder the operation of the device.

### SUMMARY OF THE INVENTION

The invention provides a method of forming an isolation film of a semiconductor device, wherein an inclined trench profile is formed in order to facilitate gap fill and prevent the occurrence of voids.

A method of forming an isolation film of a semiconductor device includes the steps of sequentially depositing a pad oxide film, a pad nitride film, and a hard mask on a semiconductor substrate; selectively etching the hard mask, the pad nitride film, and the pad oxide film; etching the semiconductor substrate using HBr and O₂, thus forming trenches; forming sidewall oxide films on sidewalls of the trenches; and burying the trenches to form the isolation film.

### BRIEF DESCRIPTION OF THE DRAWINGS

A more compete appreciation of the invention, and many of the attendant advantages thereof, will be readily apparent as the same becomes better understood by reference to the following detailed description when considered in conjunction with the accompanying drawings in which like reference symbols indicate the same or similar components, wherein:

FIGS. 1a to 1c are cross-sectional views illustrating process steps of a method of forming an isolation film of a semiconductor device according to an embodiment of the invention.

### DETAILED DESCRIPTION OF EMBODIMENTS

In the following detailed description, only a certain exemplary embodiment of the invention is shown and described, simply by way of illustration.

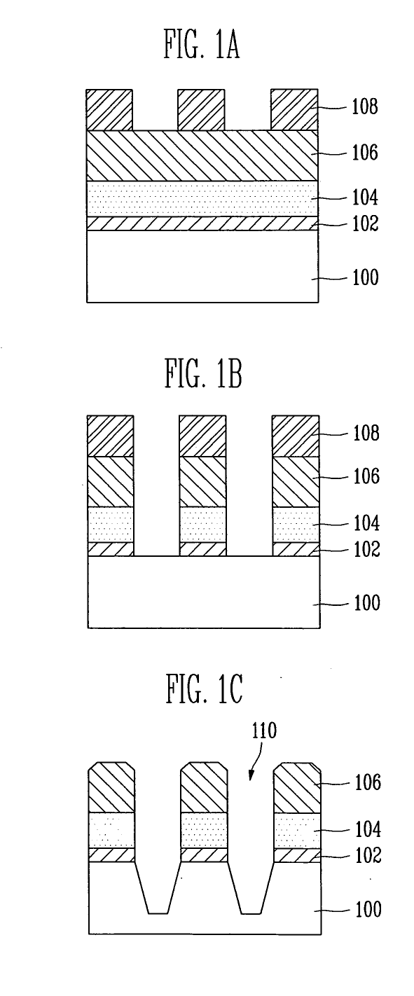

FIGS. 1a to 1c are cross-sectional views illustrating process steps of a method of forming an isolation film of a semiconductor device according to an embodiment of the invention.

Referring to FIG. 1a, a pad oxide film 102, a pad nitride film 104, and a hard mask 106 are sequentially formed on a semiconductor substrate 100. The hard mask 106 may be formed using an oxide film, an oxynitride film, a nitride film or the like. A photoresist pattern 108 is formed on the hard mask 106.

Referring to FIG. 1b, the hard mask 106, the pad nitride film 104, and the pad oxide film 102 are etched back using the photoresist pattern 108 as an etch mask. When etching the hard mask 106, any suitable etch system may be used, without regard to the type of plasma, such as reactive ion etching (RIE), magnetron enhanced reactive ion etching (ME-RIE), inductively coupled plasma (ICP), electron cyclotron resonance (ECR) and helicon.

Referring to FIG. 1c, after the photoresist pattern 108 is stripped, the semiconductor substrate 100 is etched to a give depth using the hard mask 106 as an etch mask, thereby forming trenches 110. The semiconductor substrate 100 may be etched using HBr and O₂ and may be etched using any suitable etch apparatus, regardless of the plasma type such as RIE, ME-RIE, ICP, ECR, and Helicon.

Br has a vaporization temperature of 154° C. at which it may be vaporized when reacting with the semiconductor substrate. Accordingly, since Br is difficult to evaporate compared with Cl₂, a profile having a slope of 82 degrees to 86 degrees can be formed while remaining on the trench sidewall.

Meanwhile, before the semiconductor substrate 100 is etched, the semiconductor substrate 100 may be etched using HBr and O₂ after top corners are rounded. Upon etching of the semiconductor substrate 100, a bias power of 100W to 1000W may be applied in order to prevent the oxidization of the semiconductor substrate 100.

Furthermore, HBr and O₂ may be applied to a general shallow trench isolation (STI) or self-aligned shallow trench isolation (STI) formation method, or may be applied to a multi-trench formation method with different depths from that of a single trench formation method with a constant depth.

After a sidewall oxide film (not shown) is formed on sidewalls of the trenches 110, an insulating material (not shown) is deposited on the entire surface so that the trenches 110 are buried. CMP is performed on the insulating material so that the pad nitride film 104 is exposed, thereby removing the pad nitride film 104 and forming the isolation film. The insulating material may be a high density plasma (HDP) oxide film.

As described above, according to the invention, trench profiles having a slope are formed using HBr and O₂. Therefore, ISO gap fill can be facilitated and voids are not generated. Accordingly, the invention is advantageous in that it can secure the reliability of devices and can improve the yield through ISO module process set-up.

While the invention has been described in connection with practical exemplary embodiments the invention is not limited to the disclosed embodiments, but, to the contrary, is intended to cover various modifications and equivalent arrangements included within the spirit and scope of the appended claims.

What is claimed is:

1. A method of forming an isolation film of a semiconductor device, the method comprising the steps of:
sequentially depositing a pad oxide film, a pad nitride film, and a hard mask on a semiconductor substrate;
selectively etching the hard mask, the pad nitride film, and the pad oxide film;
etching the semiconductor substrate using HBr and O₂, thus forming trenches;
forming sidewall oxide films on sidewalls of the trenches; and
burying the trenches to form the isolation film.

2. The method of claim 1, comprising forming the hard mask using any one of an oxide film, an oxynitride film, and a nitride film.

3. The method of claim 1, comprising forming the trenches by making rounding top corners of the trenches and then etching the semiconductor substrate using HBr and O₂.

4. The method of claim 1, comprising applying the trenches with a bias power of 100W to 1000W in order to prevent the oxidization of the semiconductor substrate.

5. The method of claim 1, wherein the trenches include a single trench with a uniform depth and multi-trenches with different depths.

6. The method of claim 1, wherein the step of forming the isolation film comprises the steps of:
depositing an insulating material on the entire surface so that the trenches are buried;
performing chemical mechanical polishing to expose the pad nitride film; and
stripping the pad nitride film.
